(19) United States
(12) Patent Application Publication
(10) Pub. No.: US 2024/0298471 A1
(43) Pub. Date: Sep. 5, 2024

(54) DISPLAY DEVICE

(71) Applicant: SHARP KABUSHIKI KAISHA, Osaka (JP)

(72) Inventor: TAMOTSU SAKAI, Sakai City, Osaka (JP)

(21) Appl. No.: 18/278,479

(22) PCT Filed: Mar. 1, 2021
(86) PCT No.: PCT/JP2021/007763

§ 371 Date: Aug. 23, 2023

(51) Int. Cl. H10K 59/121; H10K 59/131

(52) U.S. Cl. CPC H10K 59/1216; H10K 59/131

(57) ABSTRACT

(i) A holding capacitor formed of a second electrode serving as an upper electrode, a first electrode serving as a lower electrode, a second passivation film sandwiched between the second electrode and the first electrode, and an upper gate insulating film, (ii) a drive transistor including a gate electrode connected to the holding capacitor are included, and a plurality of pixel circuits arranged in a matrix, and a first connection wiring line electrically connecting the first electrodes of two pixel circuits adjacent to each other in a row direction are included, the second electrode being formed in an island shape, and the entirety of an outer peripheral end of the second electrode overlapping the first electrode in a plan view.

### TECHNICAL FIELD

The disclosure relates to a display device.

### BACKGROUND ART

A display device including a plurality of pixel circuits arranged in a matrix is known as a prior art. PTLs 1 to 3 each disclose a display device including a plurality of pixel circuits.

In such a display device, for the sake of display quality, a power source potential needs to be supplied to the entirety of a display region with a sufficiently low resistance and sufficient capacitance of a holding capacitor needs to be ensured. The capacitance of the holding capacitor is proportional to areas, in a plan view, of an upper electrode and a lower electrode that form the holding capacitor, and is inversely proportional to a thickness of an insulating layer sandwiched between the upper electrode and the lower electrode.

On the other hand, higher definition is also required. Thus, there is provided a configuration in which the upper electrodes of the holding capacitors of the two pixel circuits adjacent to each other in the row direction are connected to each other by a connection wiring line formed in the same layer as the upper electrodes, and function as a part of a power source line extending in the row direction and supplying the power source potential.

### CITATION LIST

### Patent Literature

PTL 1: JP 2019-144454 A
PTL 2: JP 2020-112676 A
PTL 3: JP 2020-118952 A

### SUMMARY OF INVENTION

### Technical Problem

However, in the configuration in which the upper electrodes are connected to each other as described above, the upper electrodes (or the connection wiring lines) cross an outer peripheral end of the lower electrode. The insulating layer sandwiched between the upper electrode and lower electrode is thin to increase the capacitance of the holding capacitor. In the vicinity of the outer peripheral end of the lower electrode, the insulating layer sandwiched between the upper electrode and the lower electrode is thinner (or disconnected) due to a step. For these reasons, an electrical short circuit tends to easily occur between the upper electrode and the lower electrode of the holding capacitor. As a result, there is a problem that manufacturing yield of the display device is low.

### Solution to Problem

To solve the above problem, a display device according to an aspect of the disclosure includes a holding capacitor formed of an upper electrode, a lower electrode, and a first insulating layer sandwiched between the upper electrode and the lower electrode; (ii) a drive transistor including a gate electrode connected to the holding capacitor; a plurality of pixel circuits arranged in a matrix; and a first connection wiring line electrically connecting the upper electrodes of two of the plurality of pixel circuits adjacent to each other in a row direction or the lower electrodes of two of the plurality of pixel circuits adjacent to each other in the row direction, wherein the upper electrode is formed in an island shape, and the entirety of an outer peripheral end of the upper electrode overlaps the lower electrode in a plan view.

### Advantageous Effects of Invention

According to an aspect of the disclosure, manufacturing yield of display devices can be improved.

### BRIEF DESCRIPTION OF DRAWINGS

FIG. 1 is a flowchart illustrating an example of a manufacturing method of a flexible EL device according to a first embodiment of the disclosure.

FIG. 2 is a cross-sectional view illustrating a configuration example of the flexible EL device according to the first embodiment of the disclosure.

FIG. 3 is a schematic view illustrating an example of a schematic configuration of a thin film transistor layer according to the first embodiment of the disclosure.

FIG. 4 is a circuit diagram illustrating an example of a schematic configuration of a pixel circuit according to the first embodiment of the disclosure.

FIG. 5 is a partial layout diagram illustrating the vicinity of a holding capacitor of a comparative example.

FIG. 6 is a cross-sectional view taken along arrow A-A in FIG. 5.

FIG. 7 is a partial layout diagram illustrating the vicinity of a holding capacitor according to the first embodiment of the disclosure.

FIG. 8 is a cross-sectional view taken along arrow C-C in FIG. 7.

FIG. 9 is a cross-sectional view taken along arrow D-D in FIG. 7.

FIG. 10 is a cross-sectional view taken along arrow E-E in FIG. 7.

FIG. 11 is a cross-sectional view illustrating a configuration example of a flexible EL device according to a second embodiment of the disclosure.

FIG. 12 is a partial layout diagram illustrating the vicinity of a holding capacitor according to the second embodiment of the disclosure.

FIG. 13 is a cross-sectional view taken along arrow F-F in FIG. 11.

### DESCRIPTION OF EMBODIMENTS

### First Embodiment

Hereinafter, an embodiment of the disclosure will be described in detail.

In the disclosure, “same layer” means a layer formed through the same process (film formation step), “lower layer” means a layer formed through a process before that of the comparison layer, and “upper layer” means a layer formed through a process after that of the comparison layer.

### Manufacturing Method for EL Device

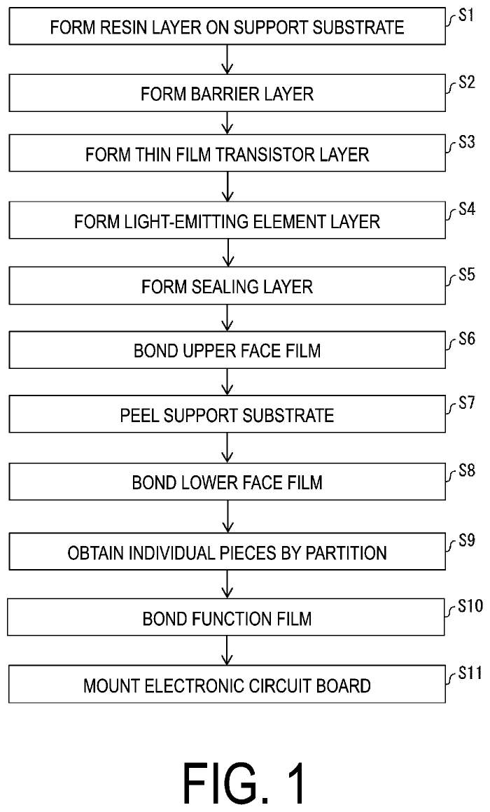

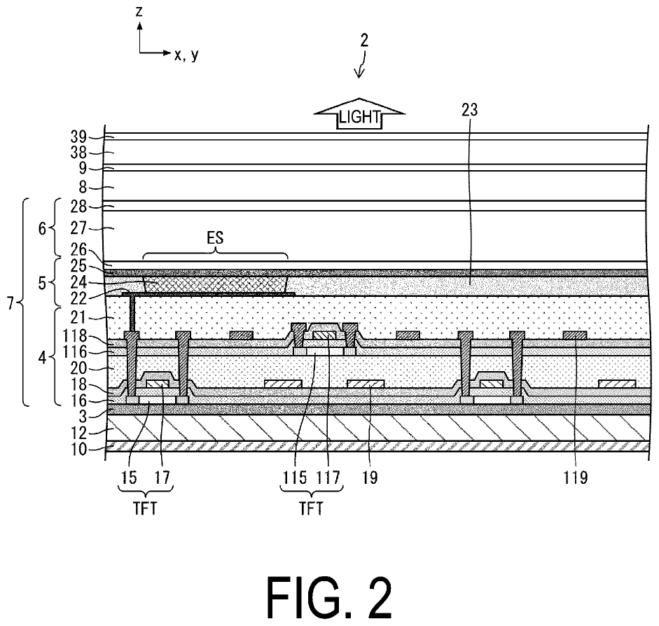

FIG. 1 is a flowchart illustrating an example of a manufacturing method for a flexible EL device (display device). FIG. 2 is a cross-sectional view illustrating a configuration example of the flexible EL device.

As illustrated in FIG. 1 and FIG. 2, first, a resin layer 12 is formed on a support substrate such as a glass substrate (step S1). Next, a barrier layer 3 is formed (step S2). Next, a thin film transistor layer 4 including a gate insulating film 16, passivation films 18, 20, and an organic interlayer film 21 is formed (step S3). Next, a light-emitting element layer (e.g., an OLED element layer) 5 is formed (step $4). Next, a sealing layer 6 including inorganic sealing films 26 and 28, and an organic sealing film 27, is formed to obtain a layered body 7 (step S5).

Next, an upper face film 9 is bonded to the layered body 7 via an adhesive layer 8 (step S6). Next, the lower face of the resin layer 12 is irradiated with a laser light through the glass substrate, and the glass substrate is peeled off from the layered body 7 (step S7). Here, the lower face (the interface with the glass substrate) of the resin layer 12 is altered by ablation, and the bonding force between the resin layer 12 and the glass base material is reduced. Subsequently, the base material 10 (e.g., a lower face film made of PET or the like) is bonded to the lower face of the resin layer 12 via an adhesive layer (step S8).

Subsequently, the layered body 7 is divided along with the base material 10 to be split into individual pieces (step S9). Next, a function film 39 is bonded via an adhesive layer 38 (step S10). Next, an electronic circuit board is mounted on an end portion of the thin film transistor layer 4 (step S11). As a result, an EL device 2 according to the first embodiment illustrated in FIG. 2 is obtained. Each of the steps above is performed by a manufacturing apparatus of an EL device.

Note that if manufacturing a non-flexible EL device, steps S5 to S8 may be omitted.

Examples of the material of the resin layer 12 include polyimide, epoxy, and polyamide. Examples of the material of the lower face film 10 include polyethylene terephthalate (PET).

The barrier layer 3 is a layer that inhibits moisture or impurities from reaching the thin film transistor layer 4 and the light-emitting element layer 5 when the EL device is being used, and can be made of a silicon oxide film, a silicon nitride film, or a silicon oxynitride film, or by a layered film of these formed by, for example, chemical vapor deposition (CVD).

The thin film transistor layer 4 includes a lower semiconductor film 15 (semiconductor layer), a lower gate insulating film 16 (insulating layer) formed in an upper layer than the lower semiconductor film 15, a lower gate electrode layer 17 (first metal layer) formed in an upper layer than the lower gate insulating film 16, a first passivation film 18 (insulating layer) formed in an upper layer than the lower gate electrode layer 17, an intermediate wiring line layer 19 (second metal layer) formed in an upper layer than the first passivation film 18, a second passivation layer 20 (insulating layer) formed in an upper layer than the intermediate wiring line layer 19, an upper semiconductor film 115 formed in an upper layer than the second passivation layer 20, an upper gate insulating film 116 (insulating layer) formed in an upper layer than the upper semiconductor film 115, an upper gate electrode layer 117 (third metal layer) formed in an upper layer than the upper gate insulating film 116, a third passivation film 118 (insulating layer) formed in an upper layer than the upper gate electrode layer 117, a source wiring line layer 119 (fourth metal layer) formed in an upper layer than the third passivation film 118, and an organic interlayer film (flattening film) 21 formed in an upper layer than the source wiring line layer 119.

The lower semiconductor film 15, the lower gate insulating film 16, the lower gate electrode layer 17, the intermediate wiring line layer 19, the upper semiconductor film 115, the upper gate electrode layer 117, and the source wiring line layer 119 are patterned in accordance with the circuit and terminals formed in the thin film transistor 4. The lower semiconductor film 15 and the upper semiconductor film 115 are patterned and doped in accordance with the circuit formed in the thin film transistor 4.

The lower semiconductor film 15 and the upper semiconductor film 115 are each made of, for example, a low-temperature polysilicon (LPTS) or an oxide semiconductor such as InGaZnO-based oxide semiconductor.

The lower gate insulating film 16, the upper gate insulating film 116, and the first to third passivation films 18, 20, and 118 may be each made of a silicon oxide (SiOx) film or a silicon nitride (SiNx) film, or a layered film thereof, formed by CVD, for example.

The lower gate electrode layer 17, the intermediate wiring line layer 19, the upper gate electrode layer 117, and the source wiring line layer 119 are each made of a single layer film or a layered film of a metal. The metal includes, for example, at least one of aluminum (Al), tungsten (W), molybdenum (Mo), tantalum (Ta), chromium (Cr), titanium (Ti), and copper (Cu). Note that, although the thin film transistor (TFT) provided with the lower semiconductor film 15 as a channel and the gate electrode formed of the lower gate electrode layer 17 is illustrated as a top gate structure in FIG. 2, the transistor may have a bottom gate structure (when the TFT channel is an oxide semiconductor, for example). Note that, although the TFT provided with the upper semiconductor film 115 as a channel and the gate electrode formed of the upper semiconductor film 115 is illustrated as having the top gate structure in FIG. 2, the TFT may have the bottom gate structure (when the TFT channel is the oxide semiconductor, for example).

The organic interlayer film 21 may be formed of a coatable photosensitive organic material, such as polyimide or acrylic, for example.

The light-emitting element layer 5 (e.g., an organic light-emitting diode layer, a quantum dot light-emitting diode) includes a pixel electrode 22 (e.g., an anode electrode) formed in an upper layer than the organic interlayer film 21, an organic insulating film 23 that covers an edge of the pixel electrode 22, an active layer 24 formed in an upper layer than the pixel electrode 22, and a common electrode 25 formed in an upper layer than the active layer 24. A light-emitting element (e.g., an organic light-emitting diode or a quantum dot diode) is configured by the pixel electrode 22, the active layer 24, and the common electrode 25. The organic insulating film 23 in an active area DA functions as a bank (pixel partition) that defines a subpixel.

The organic insulating film 23 may be made of a coatable photosensitive organic material such as polyimide or acrylic, for example. For example, the organic insulating film 23 can be applied in the active area DA and a non-active area NA by an ink-jet method.

The active layer 24 is formed in a region surrounded by a partition 23 (subpixel region) using photolithography, vapor deposition, or an ink-jet method. When the light-emitting element layer 5 is an organic light-emitting diode (OLED) layer, for example, the active layer 24 is formed by layering a hole injection layer, a hole transport layer, a light-emitting layer, an electron transport layer, and an electron injection layer in this order from the lower layer side. Note that one or more of the active layers 24 may be a common layer (shared by a plurality of pixels).

The first electrode (an anode electrode) 22 is configured by, for example, layering indium tin oxide (ITO) and an alloy including silver (Ag), and has light reflectivity. The second electrode (e.g., a cathode) 25 is a common electrode, and may be formed of a transparent metal such as ITO or indium zinc oxide (IZO).

In a case where the light-emitting element layer 5 is an OLED layer, holes and electrons are recombined inside the active layer 24 due to a drive current between the pixel electrode 22 and the common electrode 25, and excitons generated in accordance with the recombination fall to a ground state, whereby light is emitted. The light-emitting element layer 5 is not limited to the configuration including an OLED element, and may include an inorganic light-emitting diode or a quantum dot light-emitting diode. In the light-emitting element layer 5, a light-emitting element ES is formed for each subpixel.

The light-emitting element layer 5 is covered with the sealing layer 6, and the sealing layer 6 prevents foreign matter, such as water or oxygen, from penetrating into the light-emitting element layer 5. The sealing layer 6 includes a first inorganic sealing film 26 covering the organic insulating film 23 and the common electrode 25, an organic sealing film 27 that functions as a buffer film and is formed in an upper layer than the first inorganic sealing film 26, and a second inorganic sealing film 28 covering the first inorganic sealing film 26 and the organic sealing film 27.

Each of the first inorganic sealing film 26 and the second inorganic sealing film 28 may be made of, for example, a silicon oxide film, a silicon nitride film or a silicon oxynitride film, or a layered film thereof, formed by CVD using a mask. The organic sealing film 27 is a transparent organic insulating film that is thicker than the first inorganic sealing film 26 and the second inorganic sealing film 28, and may be formed of a coatable photosensitive organic material such as polyimide or acryl. For example, after the first inorganic sealing film 26 is coated, by an ink-jet method, with an ink containing such an organic material, the ink is cured by ultraviolet (UV) irradiation.

The function film 39 has, for example, an optical compensation function, a touch sensor function, or a protection function. In a case where a layer having one or more of these functions is layered in an upper layer than the light-emitting element layer 5, the function film 39 may be made thinner or omitted. The electronic circuit board is an IC chip or a flexible printed circuit board (FPC) mounted on a plurality of terminals TM, for example.

Of the components of the EL device 2 described above, the disclosure particularly relates to the thin film transistor layer 4.

### Thin Film Transistor Layer

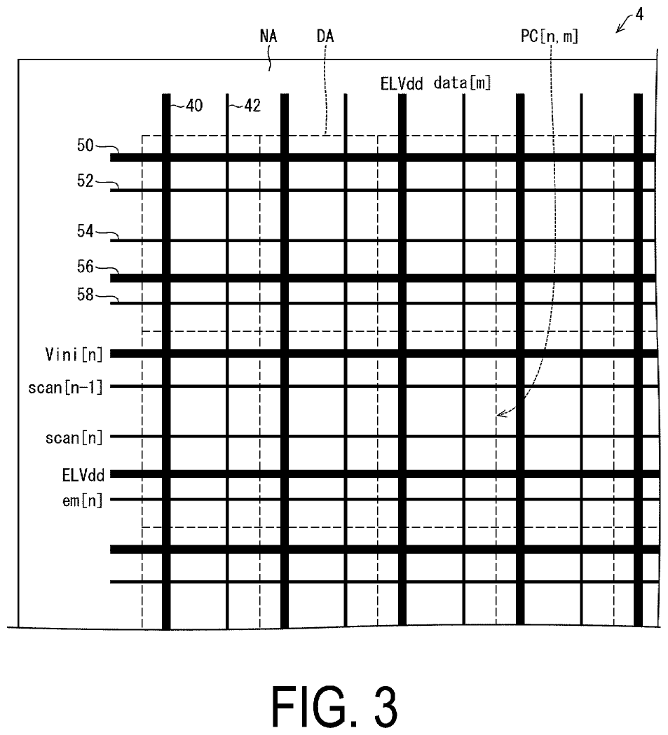

FIG. 3 is a schematic view illustrating an example of a schematic configuration of the thin film transistor layer 4 according to the first embodiment of the disclosure.

As illustrated in FIG. 3, the thin film transistor layer 4 includes a plurality of pixel circuits PC arranged in a matrix in the active area DA. Hereinafter, the pixel circuit PC arranged in the n-th row and the m-th column is referred to as a pixel circuit PC[n, m]. Although not illustrated, the thin film transistor layer may optionally include one or more of a source drive circuit, a gate drive circuit, a display control circuit, and a lead-out wiring line in the non-active area NA surrounding the active area DA.

Wiring lines 40, 42, 50, 52, 54, 56, and 58 for supplying a signal or a constant potential to each pixel circuit PC[n, m] extend in the active area DA of the thin film transistor layer 4. The wiring lines 40 and 42 extend substantially along the column direction and are usually formed of the source wiring line layer 119. The wiring lines 50, 52, 54, 56, and 58 extend substantially along the row direction.

The wiring line 40 and the wiring line 56 passing through the pixel circuit PC[n, m] supply a high potential ELVdd. The wiring line 40 and the wiring line 56 passing through the pixel circuit PC[n, m] are connected to each other in the pixel circuit PC[n, m]. The high potential ELVdd is a constant voltage.

The wiring line 42 passing through the pixel circuit PC[n, m] supplies a source signal data[m] based on image data.

The wiring line 50 passing through the pixel circuit PC[n, m] is a power line for supplying an initialization potential Vini[n] of the pixel circuit PC in the n-th row.

The wiring line 52 passing through the pixel circuit PC[n, m] is a signal line for supplying a scanning signal scan[n-1] of the pixel circuit PC in the (n−1)-th row. The scanning signal Scan[n-1] is turned on only during a period in which the source signal is written into the holding capacitor of the pixel circuit PC in the (n−1)-th row.

The wiring line 54 passing through the pixel circuit PC[n, m] is the signal line for supplying the scanning signal scan[n] of the pixel circuit PC in the n-th row. The scanning signal Scan[n] is turned on only during a period in which the source signal is written into the holding capacitor of the pixel circuit PC in the n-th row.

The wiring line 58 passing through the pixel circuit PC[n, m] is a signal line for supplying a light emission signal em[n] of the pixel circuit PC in the n-th row. The light emission signal Em[n] is turned on only during a period in which the light-emitting element of the pixel circuit PC in the n-th row is made to emit light.

### Pixel Circuit

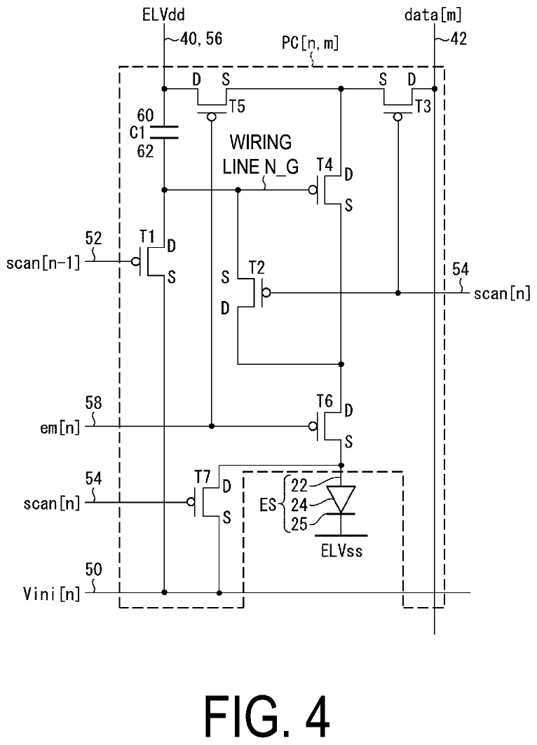

FIG. 4 is a circuit diagram illustrating an example of a schematic configuration of the pixel circuit PC[n, m] according to the first embodiment of the disclosure.

As illustrated in FIG. 4, the pixel circuit PC[n, m]is connected to the wiring lines 40, 42, 50, 52, 54, 56, 58 and the light-emitting element ES. The pixel circuit PC[n, m] includes a holding capacitor C1, first to seventh thin film transistors T1 to T7, and a wiring line N_G.

The holding capacitor C1 is formed of a pair of electrodes (a first electrode 60 and a second electrode 62). The first electrode 60 is connected to the wiring line 40 or the wiring line 56.

The first transistor T1 includes a gate electrode connected to the wiring line 52, a source electrode connected to the wiring line 50, and a drain electrode connected to the second electrode 62 of the holding capacitor C1 through the wiring line N_G.

The second transistor T2 includes a gate electrode connected to the wiring line 54, and a source electrode connected to the second electrode 62 of the holding capacitor C1 through the wiring line N_G.

The third transistor T3 includes a gate electrode connected to the wiring line 54, and a drain electrode connected to the wiring line 42.

The fourth transistor T4 includes a gate electrode connected to the second electrode 62 of the holding capacitor C1 through the wiring line N_G, a source electrode connected to a drain electrode of the second transistor T2, and a drain electrode connected to the source electrode of the third transistor T3.

The fifth transistor T5 includes a gate electrode connected to the wiring line 58, a source electrode connected to the drain electrode of the fourth transistor T4, and a drain electrode connected to the wiring line 40 or the wiring line 56.

The sixth transistor T6 includes a gate electrode connected to the wiring line 58, a source electrode connected to the light-emitting element ES, and a drain electrode connected to the source electrode of the fourth transistor T4.

The seventh transistor T7 includes a gate electrode connected to the wiring line 54, a source electrode connected to the wiring line 50, and a drain electrode connected to the source electrode of the sixth transistor T6.

One or more of the first to seventh transistors T1 to T7, for example, the third transistor T3, the fourth transistor T4, the fifth transistor T5, and the sixth transistor T6 may be TFTs each including the lower semiconductor film 15 as a channel. The others of the first to seventh transistors T1 to T7, for example, the first transistor T1, the second transistor T2, and the seventh transistor T7 may be TFTs each including the upper semiconductor film 115 as the channel.

With the circuit configuration described above, the high potential ELVdd (constant potential) is applied to the first electrode 60 of the holding capacitor C1. The second electrode 62 of the holding capacitor C1 is initialized to the initialization potential Vini[n] during a period in which the scanning signal Scan[n-1] is on, and the source signal data[m] is written during a period in which the scanning signal Scan[n] is on. The fourth transistor T4 is a drive transistor that controls the current flowing from the wiring line 40 or the wiring line 56 to the light-emitting element ES through the fifth transistor T5, the fourth transistor T4, and the sixth transistor T6 during the period in which the light emission signal em[n] is on, in accordance with the potential of the second electrode 62 of the holding capacitor C1.

### Holding Capacitor of Comparative Example

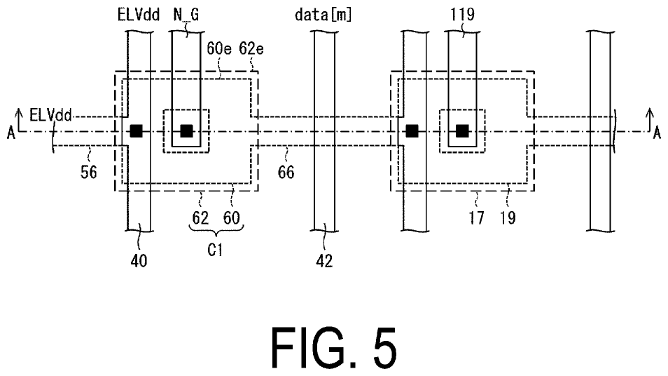

FIG. 5 is a partial layout diagram illustrating the vicinity of the holding capacitor C1 of a comparative example. For ease of understanding, in FIG. 5, the lower gate electrode layer 17 is indicated by a broken line, the intermediate wiring line layer 19 is indicated by a dotted line, the source wiring line layer 119 is indicated by a solid line, and other layers are omitted.

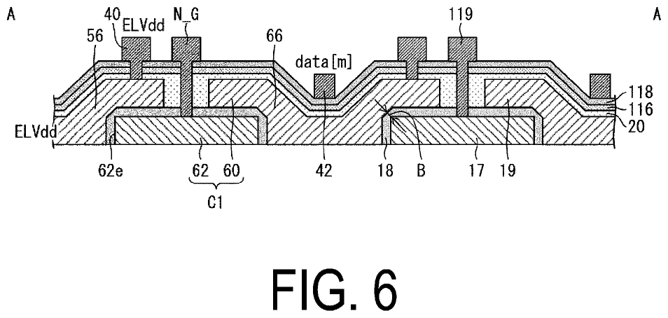

FIG. 6 is a cross-sectional view taken along arrow A-A in FIG. 5. For ease of understanding, FIG. 6 illustrates the lower gate electrode layer 17, the first passivation film 18, the intermediate wiring line layer 19, the second passivation film 20, the upper gate insulating film 116, the third passivation layer 118, and the source wiring line layer 119, and other layers are omitted.

As illustrated in FIGS. 5 and 6, in the comparative example, the second electrode 62 as the lower electrode of the holding capacitor C1 is formed of the lower gate electrode layer 17 in an island shape. The first electrode 60 of the holding capacitor C1 as the upper electrode is formed of the intermediate wiring line layer 19 so as to overlap the second electrode 62. Further, a first connection wiring line 66 that connects the first electrodes 60 adjacent to each other in the row direction is formed of the intermediate wiring line layer 19. As a result, the holding capacitor C1 of the comparative example is formed of the second electrode 62, the first electrode 60, and the first passivation layer 18 sandwiched between the first electrode 60 and the second electrode 62. Further, the first electrode 60 and the first connection wiring line 66 function as the wiring line 56 for supplying the high potential ELVdd.

In the disclosure, of the first electrode 60 and the second electrode 62 constituting the holding capacitor C1, an electrode formed first (that is, in a lower layer) is referred to as a “lower electrode”, and an electrode formed later (that is, in an upper layer) is referred to as an “upper electrode”. The lower electrode and the upper electrode substantially overlap each other in a plan view. The lower electrode is located on a lower side of the upper electrode, and the upper electrode is located on an upper side of the lower electrode.

To ensure the display quality of the EL device 2, the amount of current flowing to the light-emitting element ES is required to be stable. Specifically, in the configurations illustrated in FIG. 3 and FIG. 4, the high potential ELVdd needs to be supplied to the pixel circuit PC[n, m] with a sufficiently low resistance and to ensure that the capacitance of the holding capacitor C1 is sufficiently large. On the other hand, for the sake of higher definition, a reduction in the area of the pixel circuit PC[n, m] is also required.

In the configuration of the comparative example illustrated in FIG. 5 and FIG. 6, the area of the pixel circuit PC can be made smaller as compared with the configuration in which the first electrode 60 and the wiring line 56 are separately provided. Thus, display quality is ensured and higher definition can be achieved.

However, in the configuration of the comparative example illustrated in FIG. 5 and FIG. 6, the first electrode 60 (or the first connection wiring line 66) serving as the upper electrode crosses an outer peripheral end 62e of the second electrode 62 serving as the lower electrode. For the holding capacitor C1 to have a sufficient electrostatic capacitance, the first passivation layer 18 between the first electrode 60 and the second electrode 62 needs to be sufficiently thin. Thus, in the vicinity of the outer peripheral end 62e of the second electrode 62 (the position indicated by an arrow B in FIG. 6), the first passivation layer 18 is thin due to a step, and may be disconnected in some cases. Thus, an electrical short circuit tends to easily occur between the first electrode 60 (or the first connection wiring line 66) and the second electrode 62 in the vicinity of the outer peripheral end 62e of the second electrode 62.

### Holding Capacitor of Disclosure

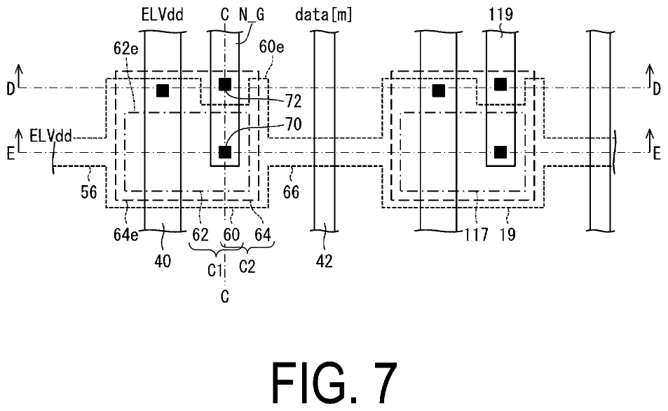

FIG. 7 is a partial layout diagram illustrating the vicinity of the holding capacitor C1 according to the first embodiment of the disclosure. For ease of understanding, in FIG. 7, the lower gate electrode layer 17 is indicated by a broken line, the intermediate wiring line layer 19 is indicated by a dotted line, the upper gate electrode layer 117 is indicated by an alternate long and short dash line, the source wiring line layer 119 is indicated by a solid line, and other layers are omitted.

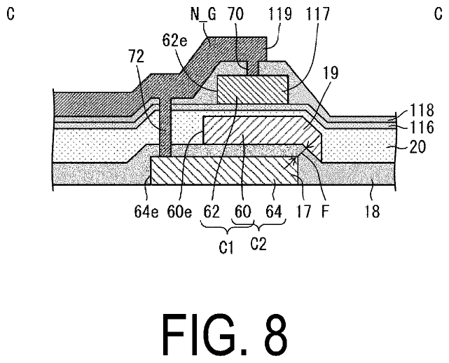

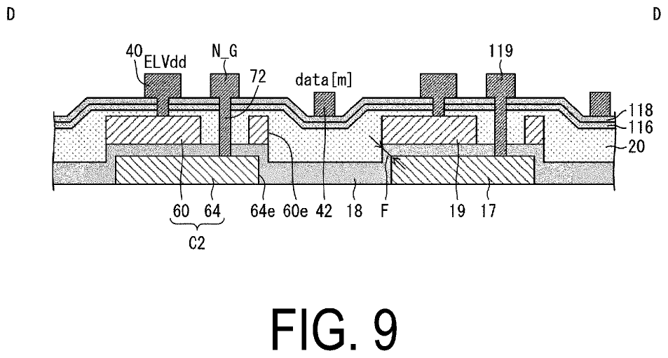

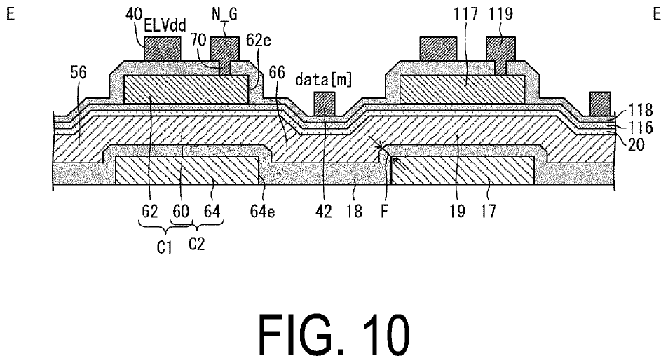

FIG. 8 is a cross-sectional view taken along arrow C-C in FIG. 7. FIG. 9 is a cross-sectional view taken along arrow D-D in FIG. 7. FIG. 10 is a cross-sectional view taken along arrow E-E in FIG. 7. For ease of understanding, FIG. 8, FIG. 9, and FIG. 10 illustrate the lower gate electrode layer 17, the first passivation film 18, the intermediate wiring line layer 19, the second passivation film 20, the upper gate insulating film 116, the third passivation layer 118, and the source wiring line layer 119, and other layers are omitted.

As illustrated in FIG. 7 to FIG. 10, in the first embodiment of the disclosure, the second electrode 62 as the upper electrode of the holding capacitor C1 is formed of the upper gate electrode layer 117 in an island shape. The first electrode 60 of the holding capacitor C1 as the lower electrode is formed of the intermediate wiring line layer 19 so as to overlap the second electrode 62. Further, a first connection wiring line 66 that connects the first electrodes 60 adjacent to each other in the row direction is formed of the intermediate wiring line layer 19. As a result, the holding capacitor C1 according to the first embodiment is formed of the second electrode 62, the first electrode 60, the second passivation layer 20 (first insulating layer) sandwiched between the first electrode 60 and the second electrode 62, the upper gate insulating film 116, and the third passivation layer 118. Further, the first electrode 60 and the first connection wiring line 66 also function as the wiring line 56 for supplying the high potential ELVdd.

Note that the second electrode 62 serving as the upper electrode is formed so as to be located inside the first electrode 60 serving as the lower electrode in a plan view. That is, the entirety of the outer peripheral end 62e of the upper electrode overlaps the lower electrode, and the upper electrode does not cross the outer peripheral end 60e of the lower electrode. The configuration in which the upper electrode is located inside the lower electrode includes a configuration in which some or all of the outer peripheral end 62e of the upper electrode coincides with the outer peripheral end 60e of the lower electrode.

In the configuration of the first embodiment illustrated in FIG. 7 to FIG. 10, the entirety of the outer peripheral end 62e of the upper electrode (second electrode 62) overlaps the lower electrode (first electrode 60). Thus, unlike the configuration of the comparative example illustrated in FIGS. 5 and 6, an effect in which an electrical short circuit is less likely to occur between the lower electrode (first electrode 60) and the upper electrode (second electrode 62) is achieved. Further, similarly to the configuration of the comparative example illustrated in FIG. 5 and FIG. 6, an effect of both ensuring display quality and achieving higher definition is also achieved.

Furthermore, in the first embodiment of the disclosure, the third electrode 64 as an auxiliary electrode is preferably formed of the lower gate electrode layer 17 in an island shape so as to overlap the lower electrode (first electrode 60). To additionally form an auxiliary holding capacitor C2 in parallel with the holding capacitor C1, the third electrode 64 is connected to the second electrode 62 via the wiring line N_G (second connection wiring line). As a result, the auxiliary holding capacitor C2 is formed of the first electrode 60, the third electrode 64, and the first passivation layer 18 (second insulating layer) sandwiched between the first electrode 60 and the third electrode 64. The auxiliary holding capacitor C2 is connected in parallel to the holding capacitor C1. Thus, the holding capacitance of the pixel circuit PC increases by the capacitance of the auxiliary holding capacitor C2. By increasing the holding capacitance, the display quality of the EL device 2 can be improved. Alternatively, by reducing the area of the holding capacitor C1 in a plan view, higher definition of the EL device 2 can be promoted.

Specifically, the wiring line N_G is formed in the source wiring line layer 119, is connected to the upper electrode (second electrode 62) via a first contact hole 70, and is electrically connected to the auxiliary electrode (third electrode 64) via a second contact hole 72. The second contact hole 72 may be formed not overlapping the intermediate wiring line layer 19 (specifically, the first electrode 60 formed in the intermediate wiring line layer 19).

Note that the first electrode 60 (or the first connection wiring line 66) crosses an outer peripheral end 64e of the third electrode 64. For this reason, it is preferable that the first passivation layer 18 is sufficiently thick to prevent an electrical short circuit from occurring between the first electrode 60 and the third electrode 64 in the vicinity of the outer peripheral end 64e of the third electrode 64 (the position indicated by an arrow F in FIG. 8 to FIG. 10). Specifically, it is preferable that the thickness of the first passivation layer 18 is larger than the sum of the thickness of the second passivation layer 20 and the thickness of the upper gate insulating film 116. For example, it is preferable that the thicknesses of the second passivation layer 20 and the upper gate insulating film 116 are each 50 nm, and the thickness of the first passivation layer 18 is 150 nm or more. In other words, it is preferable that the thickness of the second insulating layer between the first electrode 60 and the third electrode 64 is larger than the thickness of the first insulating layer between the first electrode 60 and the second electrode 62. Here, when there are a plurality of the insulating layers between the first electrode 60 and the second electrode 62, the thickness of the first insulating layer is the sum of the thicknesses of the plurality of insulating layers. Similarly, when there are a plurality of the insulating layers between the first electrode 60 and the third electrode 64, the thickness of the second insulating layer is the sum of the thicknesses of the plurality of insulating layers.

To achieve higher definition of the EL device 2, it is preferable that the gate electrode of the fourth transistor T4 serving as the drive transistor is integrated with the auxiliary electrode (third electrode 64) of the auxiliary holding capacitor C2. In other words, it is preferable that a part of the auxiliary electrode (third electrode 64) of the auxiliary holding capacitor C2 function as the gate electrode of the fourth transistor T4. Thus, the fourth transistor T4 is preferably a TFT including the lower semiconductor film 15 as the channel and the gate electrode formed of the lower gate electrode layer 17.

### Second Embodiment

Hereinafter, an embodiment of the disclosure will be described in detail.

Another embodiment of the present invention will be described below. Note that, for convenience of description, members having the same functions as those of the members described in the above-described embodiment will be denoted by the same reference numerals and signs, and the description thereof will not be repeated.

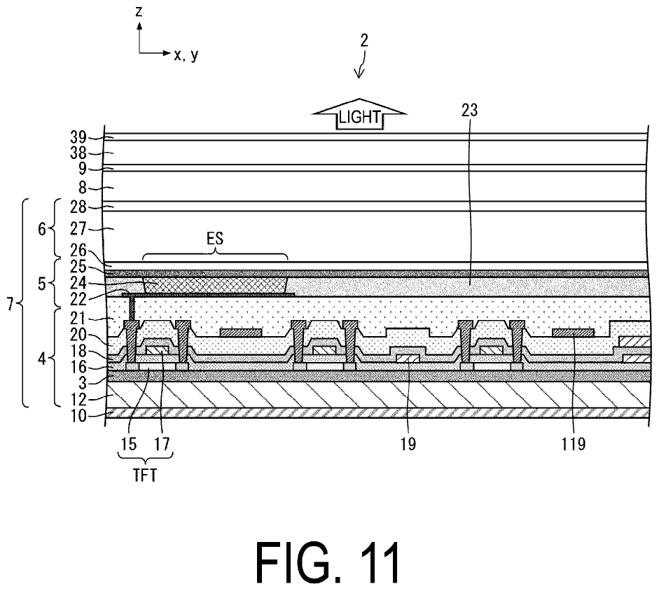

FIG. 11 is a cross-sectional view illustrating a schematic configuration example of a flexible EL device according to a second embodiment.

As illustrated in FIG. 11, similarly to the thin film transistor layer 4 according to the first embodiment described above, the thin film transistor layer 4 according to the second embodiment includes the lower semiconductor film 15 (semiconductor layer), the lower gate insulating film 16 (insulating layer), the lower gate electrode layer 17 (first metal layer), the first passivation film 18 (insulating layer), the intermediate wiring line layer 19 (second metal layer), the second passivation layer 20 (insulating layer), the source wiring line layer 119 (third metal layer) formed in an upper layer than the second passivation film 20, and the organic interlayer film (flattening film) 21 formed in an upper layer than the source wiring line layer 119.

Unlike the thin film transistor layer 4 according to the first embodiment described above, the thin film transistor layer 4 according to the second embodiment does not include the upper semiconductor film 115, the upper gate insulating film 116 (insulating film), the upper gate electrode layer 117 (third metal layer), and the third passivation film 118 (insulating film).

Similarly to the thin film transistor layer 4 according to the first embodiment described above, the thin film transistor 4 according to the second embodiment includes the plurality of pixel circuits PC.

### Holding Capacitor

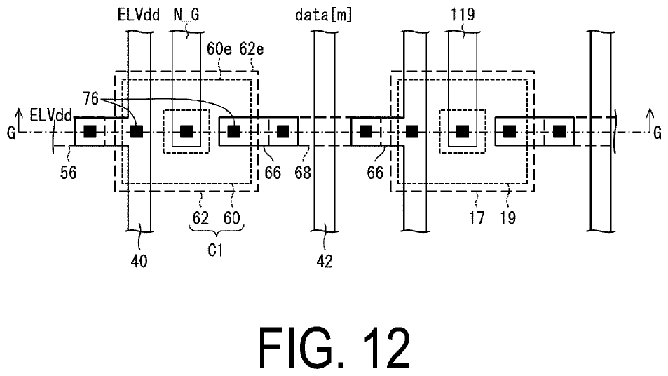

FIG. 12 is a partial layout diagram illustrating the vicinity of the holding capacitor C1 according to the second embodiment of the disclosure. For ease of understanding, in FIG. 12, the lower gate electrode layer 17 is indicated by a broken line, the intermediate wiring line layer 19 is indicated by a dotted line, the source wiring line layer 119 is indicated by a solid line, and other layers are omitted.

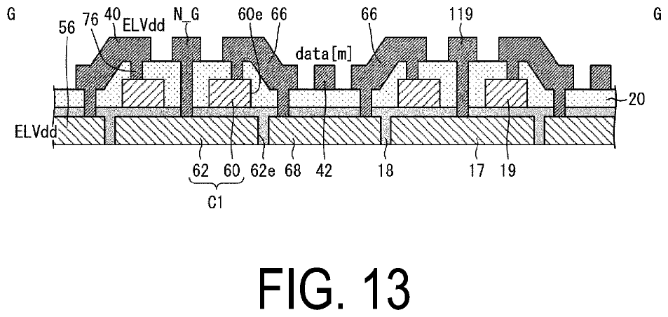

FIG. 13 is a cross-sectional view taken along arrow F-F in FIG. 12. For ease of understanding. FIG. 13 illustrates the lower gate electrode layer 17, the first passivation film 18, the intermediate wiring line layer 19, the second passivation film 20, and the source wiring line layer 119, and other layers are omitted.

As illustrated in FIGS. 12 to 13, in the second embodiment of the disclosure, the second electrode 62 as the lower electrode of the holding capacitor C1 is formed of the lower gate electrode layer 17 in an island shape. The first electrode 60 of the holding capacitor C1 as the upper electrode is formed of the intermediate wiring line layer 19 in an island shape so as to overlap the second electrode 62. Further, the first connection wiring line 66 that connects the first electrodes 60 adjacent to each other in the row direction is formed of the source wiring line layer 119. One end of the first connection wiring line 66 is electrically connected to the first electrode 60 via a third contact hole 76. An other end of the first connection wiring line 66 is connected to another first connection wiring line adjacent in the row direction via a third connection wiring line 68 formed of the lower gate electrode layer 17. As a result, the holding capacitor C1 according to the second embodiment is formed of the second electrode 62, the first electrode 60, and the first passivation layer 18 (first insulating film) sandwiched between the first electrode 60 and the second electrode 62. The first electrode 60, the first connection wiring line 66, and the third connection wiring line 68 also function as the wiring line 56 for supplying the high potential ELVdd. That is, the high potential ELVdd (constant voltage) is applied to the first electrode 60 via the first connection wiring line 66.

Note that the first electrode 60 serving as the upper electrode is formed so as to be located inside the second electrode 62 serving as the lower electrode in a plan view. That is, the entirety of the outer peripheral end 60e of the upper electrode overlap the lower electrode, and the upper electrode does not cross the outer peripheral end 62e of the lower electrode. The configuration in which the upper electrode is located inside the lower electrode includes a configuration in which some or all of the outer peripheral end 60e of the upper electrode coincides with the outer peripheral end 62e of the lower electrode.

Thus, similarly to the configuration according to the first embodiment described above, in the configuration of the second embodiment, an effect in which the electrical short circuit is less likely to occur between the first electrode 60 and the second electrode 62 is achieved, and an effect of both ensuring display quality and achieving higher definition is also achieved.

To achieve higher definition of the EL device 2, it is preferable that the gate electrode of the fourth transistor T4 serving as the drive transistor is integrated with the lower electrode (second electrode 62) of the holding capacitor C1. In other words, it is preferable that a part of the lower electrode (second electrode 62) of the holding capacitor C1 function as the gate electrode of the fourth transistor T4. Thus, the fourth transistor T4 is preferably a TFT including the lower semiconductor film 15 as the channel and the gate electrode formed of the lower gate electrode layer 17.

In the above description, an organic EL display device is exemplified to describe embodiments and modification examples, but the present invention is not limited to the organic EL display device, and may be applied to any display device provided with a plurality of pixel circuits arranged in a matrix and uses a hybrid type pixel circuit as described above. The display element that can be used in such a configuration includes, for example, an organic EL element, that is, an organic light-emitting diode (OLED), or an inorganic light-emitting diode, a quantum dot light-emitting diode (QLED) or the like.

### Supplement

A display device according to a first aspect of the present invention may include (i) a holding capacitor formed of an upper electrode, a lower electrode, and a first insulating layer sandwiched between the upper electrode and the lower electrode; (ii) a drive transistor including a gate electrode connected to the holding capacitor; a plurality of pixel circuits arranged in a matrix; and a first connection wiring line electrically connecting the upper electrodes of two of the plurality of pixel circuits adjacent to each other in a row direction or the lower electrodes of two of the plurality of pixel circuits adjacent to each other in the row direction, wherein the upper electrode is formed in an island shape, and the entirety of an outer peripheral end of the upper electrode overlaps the lower electrode in a plan view.

A display device according to a second aspect of the present invention may have a configuration in which, in the first aspect, the display device include first to fourth metal layers sequentially provided on a semiconductor layer via an insulating layer, the upper electrode is included in the third metal layer, and the lower electrode and the first connection wiring line are included in the second metal layer.

Note that in the disclosure, the configuration “include first to fourth metal layers sequentially provided on a semiconductor layer via an insulating layer” means a configuration in which at least a semiconductor layer, an insulating layer, a first metal layer, an insulating layer, a second metal layer, an insulating layer, a third metal layer, an insulating layer, and a fourth metal layer are layered in this order. Further, an additional layer may be formed in a lower layer than the semiconductor layer, between the semiconductor layer and the fourth metal layer, or in an upper layer than the fourth metal layer.

A display device according to a third aspect of the present invention may have a configuration in which, in the second aspect, the first metal layer includes an auxiliary electrode formed in an island shape, and the auxiliary electrode, the lower electrode, and a second insulating layer sandwiched between the auxiliary electrode and the lower electrode form an auxiliary holding capacitor.

A display device according to a fourth aspect of the present invention may have a configuration in which, in the third aspect, a thickness of the second insulating layer is larger than a thickness of the first insulating layer.

A display device according to a fifth aspect of the present invention may have a configuration in which, in the fourth aspect, a thickness of the second insulating layer is 150 nm or more.

A display device according to a sixth aspect of the present invention may have a configuration in which, in the fourth or fifth aspect, the display device further includes a second connection wiring line that electrically connects the auxiliary electrode to the upper electrode.

A display device according to a seventh aspect of the present invention may have a configuration in which, in the sixth aspect, the second connection wiring line is included in the fourth metal layer.

A display device according to an eighth aspect of the present invention may have a configuration in which, in the sixth or seventh aspect, the upper electrode and the second connection wiring line are connected to each other via a first contact hole, and the auxiliary electrode and the second connection wiring line are connected to each other via a second contact hole different from the first contact hole.

A display device according to a ninth aspect of the present invention may have a configuration in which, in the eighth aspect, the second contact hole does not overlap the second metal layer.

A display device according to a tenth aspect of the present invention may have a configuration in which, in any one of the third to ninth aspects, the gate electrode of the drive transistor is integrated with the auxiliary electrode.

A display device according to an eleventh aspect of the present invention may have a configuration in which, in the first aspect, the display device includes first to third metal layers sequentially provided on a semiconductor layer via an insulating layer, the upper electrode is included in the second metal layer, the lower electrode is included in the first metal layer, and the first connection wiring line is included in the third metal layer.

Note that in the disclosure, the configuration “includes first to third metal layers sequentially provided on a semiconductor layer via an insulating layer” means a configuration in which at least a semiconductor layer, an insulating layer, a first metal layer, an insulating layer, a second metal layer, an insulating layer, and a third metal layer are layered in this order. Further, an additional layer may be formed in a lower layer than the semiconductor layer, between the semiconductor layer and the third metal layer, or in an upper layer than the third metal layer.

A display device according to a twelfth aspect of the present invention may have a configuration in which, in the eleventh aspect, the upper electrode and the first connection wiring line are connected to each other via a third contact hole.

A display device according to a thirteenth aspect of the present invention may have a configuration in which, in the twelfth aspect, the first connection wiring lines of the two pixel circuits adjacent to each other in the row direction are connected to each other via the first metal layer.

A display device according to a fourteenth aspect of the present invention may have a configuration in which, in any one of the eleventh to thirteenth aspects, a gate electrode of the drive transistor is integrated with the lower electrode.

A display device according to a fifteenth aspect of the present invention may have a configuration in which, in any one of the eleventh to fourteenth aspects, a constant potential is applied to the upper electrode via the first connection wiring line.

A display device according to a sixteenth aspect of the present invention may have a configuration in which, in any one of the second to fifteenth aspects, the gate electrode of the drive transistor is included in the first metal layer.

The present invention is not limited to each of the embodiments described above, and various modifications may be made within the scope of the claims. Embodiments obtained by appropriately combining technical approaches disclosed in each of the different embodiments also fall within the technical scope of the present invention. Furthermore, novel technical features can be formed by combining the technical approaches disclosed in each of the embodiments.

### REFERENCE SIGNS LIST

15 Lower semiconductor film (semiconductor layer)
16 Lower gate insulating film (insulating layer)
17 Lower gate electrode layer (first metal layer)
18 First passivation film (insulating layer, first insulating layer, second insulating layer)
19 Intermediate wiring line layer (second metal layer)
20 Second passivation film (insulating layer, first insulating layer)
60 First electrode (upper electrode, lower electrode)
62 Second electrode (lower electrode, upper electrode)
64 Third electrode (auxiliary electrode)
66 First connection wiring line
70 First contact hole
72 Second contact hole
76 Third contact hole
116 Upper gate insulating film (insulating layer, first insulating layer)
117 Upper gate electrode layer (third metal layer)
118 Third passivation film (insulating layer, first insulating layer)
119 Source wiring line layer (fourth metal layer)
C1 Holding capacitor
C2 Auxiliary holding capacitor
ELVdd High potential (constant potential)
N_G Wiring line (second connection wiring line)
PC Pixel circuit
T4 Fourth transistor (drive transistor)

1. A display device comprising:
(i) a holding capacitor formed of an upper electrode, a lower electrode, and a first insulating layer sandwiched between the upper electrode and the lower electrode;
(ii) a drive transistor including a gate electrode connected to the holding capacitor;
a plurality of pixel circuits arranged in a matrix; and
a first connection wiring line electrically connecting the upper electrodes of two of the plurality of pixel circuits adjacent to each other in a row direction or the lower electrodes of two of the plurality of pixel circuits adjacent to each other in the row direction,
wherein the upper electrode is formed in an island shape, and the entirety of an outer peripheral end of the upper electrode overlaps the lower electrode in a plan view.

2. The display device according to claim 1, further comprising:
first to fourth metal layers sequentially provided on a semiconductor layer via an insulating layer,
wherein the upper electrode is included in the third metal layer, and
the lower electrode and the first connection wiring line are included in the second metal layer.

3. The display device according to claim 2,
wherein the first metal layer includes an auxiliary electrode formed in an island shape, and
the auxiliary electrode, the lower electrode, and a second insulating layer sandwiched between the auxiliary electrode and the lower electrode form an auxiliary holding capacitor.

4. The display device according to claim 3,
wherein a thickness of the second insulating layer is larger than a thickness of the first insulating layer.

5. The display device according to claim 4,
wherein a thickness of the second insulating layer is 150 nm or more.

6. The display device according to claim 4, further comprising:
a second connection wiring line configured to electrically connect the auxiliary electrode to the upper electrode.

7. The display device according to claim 6,
wherein the second connection wiring line is included in the fourth metal layer.

8. The display device according to claim 6,
wherein the upper electrode and the second connection wiring line are connected to each other via a first contact hole, and
the auxiliary electrode and the second connection wiring line are connected to each other via a second contact hole different from the first contact hole.

9. The display device according to claim 8,
wherein the second contact hole does not overlap the second metal layer.

10. The display device according to claim 3,
wherein the gate electrode of the drive transistor is integrated with the auxiliary electrode.

11. The display device according to claim 1, further comprising:
first to third metal layers sequentially provided on a semiconductor layer via an insulating layer,
wherein the upper electrode is included in the second metal layer,
the lower electrode is included in the first metal layer, and
the first connection wiring line is included in the third metal layer.

12. The display device according to claim 11,
wherein one end of the first connection wiring line is connected to the upper electrode via a third contact hole.

13. The display device according to claim 12,
wherein an other end of the first connection wiring line is connected to the first connection wiring line adjacent in the row direction via the first metal layer.

14. The display device according to claim 11,
wherein a gate electrode of the drive transistor is integrated with the lower electrode.

15. The display device according to claim 11,
wherein a constant potential is applied to the upper electrode via the first connection wiring line.

16. The display device according to claim 2,
wherein the gate electrode of the drive transistor is included in the first metal layer.
